(19) United States
(12) Patent Application Publication
(10) Pub. No.: US 2013/0059124 A1
(43) Pub. Date: Mar. 7, 2013

(54) METHOD OF MANUFACTURING CARBON NANOTUBE, SINGLE-CRYSTAL SUBSTRATE FOR MANUFACTURING CARBON NANOTUBE, AND CARBON NANOTUBE

(71) Applicants: Shigeo Maruyama, Tokyo (JP); Shohei Chiashi, Tokyo (JP); Hiroto Okabe, Tokyo (JP); Masami Terasawa, Tokyo (JP); Shuichi Kono, Tokyo (JP); Tadashi Sato, Tokyo (JP)

(72) Inventors: Shigeo Maruyama, Tokyo (JP); Shohei Chiashi, Tokyo (JP); Hiroto Okabe, Tokyo (JP); Masami Terasawa, Tokyo (JP); Shuichi Kono, Tokyo (JP); Tadashi Sato, Tokyo (JP)

(21) Appl. No.: 13/581,410

(22) PCT Filed: Mar. 1, 2011
(86) PCT No.: PCT/JP2011/054644

§ 371 Date: Nov. 12, 2012

(30) Foreign Application Priority Data
Mar. 1, 2010 (JP) 2010-044757

(51) Int. Cl. B32B 3/26; C30B 25/02; C30B 25/10; B82Y 40/00; B82Y 30/00

(52) U.S. Cl. 428/172; 117/88; 117/94; 117/97; 428/156; 977/742; 977/750; 977/843

(57) ABSTRACT

An R-cut substrate is prepared by cutting lumbered synthetic quartz crystal along a surface parallel to the R-face. The surface of the thus obtained R-cut substrate has a structure in which the R-face smoothest in terms of the crystal structure accounts for the most part of the surface, and the m- and r-faces are exposed on this surface to extend in a direction parallel to the X-axis albeit only slightly upon processing. After catalytic metals are arranged on the surface of the R-cut substrate, a carbon source gas is supplied onto the surface of the R-cut substrate to grow carbon nanotubes in accordance with the crystal lattice structure using the crystal metals as nuclei. This makes it possible to manufacture carbon nanotubes with a good orientation and linearity.

### BACKGROUND OF THE INVENTION

1. Field of the Invention

The present invention relates to a method of manufacturing a carbon nanotube, a single-crystal substrate for manufacturing a carbon nanotube, and a carbon nanotube.

2. Description of the Relevant Art

There are two types of carbon nanotubes (CNTs): a single-wall carbon nanotube (SWNT) formed by one cylindrically closed graphene sheet, and a multiwall carbon nanotube (MWNT) formed by a large number of cylindrically stacked coaxial graphene sheets. Each of these two types of carbon nanotubes has a minute structure with a diameter of about one to several ten nanometers and a length of about several to several hundred micrometers. Single-wall carbon nanotubes or multiwall carbon nanotubes are formed as, for example, isolated carbon nanotubes or bundled carbon nanotubes, depending on, for example, a method of manufacturing a carbon nanotube. Since carbon nanotubes exhibit the special property that they have a high conductivity or semiconductivity and additionally have an elongated structure and a high mechanical strength, their practical application is under active study. Also, carbon nanotubes are expected to be applied to devices such as an electron emission source, and the channel of an FET (Field Effect Transistor).

Carbon nanotubes can be manufactured by, for example, the arc discharge method, the laser deposition method, and the CVD (Chemical Vapor Deposition) method. Especially the CVD method is suitable for forming carbon nanotubes on the surface of a substrate by self-organization, and is therefore under active study. In the CVD method, metals (catalytic metals) such as Fe, Co, and nickel are formed on the surface of a substrate as nuclei (catalysts), and a carbon source gas such as carbon monoxide, ethanol, methanol, ether, acetylene, ethylene, ethane, propylene, propane, or methane is then supplied onto the surface of the substrate to grow carbon nanotubes on this surface.

The properties of a device which uses carbon nanotubes as constituent components considerably depend on, for example, the orientation and linearity of the carbon nanotubes for the following reasons. First, for example, as carbon nanotubes have a poorer orientation and linearity, the accuracy of alignment between the two ends of each carbon nanotube and the source and drain electrodes degrade, and the electrical conductivity of the carbon nanotubes, in turn, degrades. Second, adjacent carbon nanotubes form bundles, which cause unintended electrical interactions.

However, many difficulties are encountered in forming a minute structure such as carbon nanotubes on the surface of a substrate with a good orientation. Hence, when a method of manufacturing a carbon nanotube with a good orientation and linearity is established, it is considered to have a very high value in practical application.

Under the circumstances, as a method of manufacturing a carbon nanotube with a good orientation and linearity, a method of using a single-crystal quartz substrate or a single-crystal sapphire substrate to manufacture a single-wall carbon nanotube in accordance with its atomic structure and step pattern has been proposed (see, for example, patent literature 1). According to this method, a Y-cut, AT-cut, ST-cut, or Z-cut single-crystal quartz substrate or single-crystal sapphire substrate is prepared, processed by mechanical minor finishing, and then annealed before synthesis of carbon nanotubes, thereby forming carbon nanotubes on the single-crystal substrate. Upon such a process, the surface of the substrate is made smoother more to form carbon nanotubes on this surface.

### SUMMARY OF THE INVENTION

Unfortunately, in the method of manufacturing a carbon nanotube, that has been described in Japanese Patent Laid-Open No. 2009-528254, even when carbon nanotubes are manufactured under the same conditions, they have small variations in orientation and linearity. This makes it impossible to attain a sufficient yield in manufacturing a device having desired properties. Note that the cause of the variations in orientation and linearity of the manufactured carbon nanotubes still remains unidentified.

The present invention has been made in consideration of the above-mentioned problem, and has as its object to provide a method of manufacturing a carbon nanotube with a better orientation and linearity, a single-crystal substrate for manufacturing the carbon nanotube, and the carbon nanotube.

A method of manufacturing a carbon nanotube according to an aspect of the present invention comprises at least the steps of arranging a catalytic metal on an R-cut surface of a single-crystal substrate, which is cut parallel to an R-face of a single crystal, and heating the single-crystal substrate to a predetermined temperature and then supplying a carbon source gas to form a carbon nanotube on the R-cut surface using the catalytic metal as a nucleus.

In a method of manufacturing a carbon nanotube according to another aspect of the present invention, the single-crystal substrate may be annealed.

In a method of manufacturing a carbon nanotube according to still another aspect of the present invention, the single-crystal substrate may have the R-cut surface processed by minor finishing.

In a method of manufacturing a carbon nanotube according to still another aspect of the present invention, the single-crystal substrate may be a single-crystal sapphire substrate or a single-crystal quartz substrate.

In a method of manufacturing a carbon nanotube according to still another aspect of the present invention, the carbon nanotube may be a single-wall carbon nanotube.

A single-crystal substrate for manufacturing a carbon nanotube according to an aspect of the present invention is a single-crystal substrate for manufacturing a carbon nanotube used in a method of manufacturing a carbon nanotube, the method comprising at least the steps of arranging a catalytic metal on a surface of a single-crystal substrate, and heating the single-crystal substrate to a predetermined temperature and then supplying a carbon source gas to form a carbon nanotube on the surface using the catalytic metal as a nucleus, the substrate comprising an R-cut surface cut parallel to an R-face of a single crystal.

A carbon nanotube according to an aspect of the present invention is a carbon nanotube formed on a single-crystal substrate, wherein the single-crystal substrate comprises an R-cut surface cut parallel to an R-face of a single crystal, and the carbon nanotube is formed on the R-cut surface.

According to the present invention, an R-cut surface cut parallel to an R-face smoothest in terms of the crystal structure is used as a surface on which carbon nanotubes are to be formed, so the R-face smoothest in terms of the crystal structure accounts for the most part of the surface of the R-cut substrate even after processing. Hence, the use of a single-crystal substrate for manufacturing a carbon nanotube as mentioned above allows the carbon nanotube to grow on the smoothest R-face, thereby manufacturing a carbon nanotube with a good orientation and linearity in accordance with the crystal lattice arrangement.

### BRIEF DESCRIPTION OF THE DRAWINGS

Advantages of the present invention will become apparent to those skilled in the art with the benefit of the following detailed description of embodiments and upon reference to the accompanying drawings in which:

FIG. 1 is a perspective view of lumbered synthetic quartz crystal;

FIG. 2A is a sectional view for explaining the crystal structure of an R-cut substrate according to the embodiment;

FIG. 2B is a plan view for explaining the crystal structure of the R-cut substrate according to the embodiment;

FIG. 3 shows AFM photographs of R-cut substrates according to the embodiment;

FIG. 4 shows AFM photographs of ST-cut substrates;

FIG. 5 shows AFM photographs of X-cut substrates;

FIG. 6 shows AFM photographs of Y-cut substrates;

FIG. 7 shows AFM photographs of Z-cut substrates;

FIG. 8 is a view illustrating an example of the arrangement of an experimental apparatus used in a method of manufacturing a carbon nanotube according to the embodiment;

FIG. 9 shows SEM photographs of the surfaces of R-cut substrates according to the embodiment;

FIG. 10 shows SEM photographs of the surfaces of AT-cut substrates;

FIG. 11 shows SEM photographs of the surfaces of ST-cut substrates;

FIG. 12 shows SEM photographs of the surfaces of X-cut substrates;

FIG. 13 shows SEM photographs of the surfaces of Y-cut substrates;

FIG. 14 shows SEM photographs of the surfaces of Z-cut substrates;

FIG. 15 shows SEM photographs for explaining the influence that an etching process on an R-cut substrate has on single-wall carbon nanotubes;

FIG. 16 shows SEM photographs for explaining the influence that the partial pressure of ethanol at the time of CVD has on single-wall carbon nanotubes;

FIG. 17A is a graph showing the Raman spectra of horizontally oriented single-wall carbon nanotubes, which are measured at positions 0 μm, 5 μm, 10 μm, and 15 μm from a catalyst area;

FIG. 17B is a CCD photograph of a sample surface captured by an optical microscope which forms a Raman spectroscopic device;

FIG. 18A is an AFM photograph of a sample surface;

FIG. 18B is a graph showing the height profile of a portion indicated by a solid line in FIG. 18A;

FIG. 19A is an AFM photograph of horizontally oriented single-wall carbon nanotubes synthesized using an unetched R-cut substrate;

FIG. 19B is a graph showing the height profile of a portion indicated by a solid line in FIG. 19A; and

FIG. 19C is a distribution map of the diameters of 29 horizontally oriented single-wall carbon nanotubes, which are derived from the height profiles of the horizontally oriented single-wall carbon nanotubes.

While the invention may be susceptible to various modifications and alternative forms, specific embodiments thereof are shown by way of example in the drawings and will herein be described in detail. The drawings may not be to scale. It should be understood, however, that the drawings and detailed description thereto are not intended to limit the invention to the particular form disclosed, but to the contrary, the intention is to cover all modifications, equivalents, and alternatives falling within the spirit and scope of the present invention as defined by the appended claims.

### DETAILED DESCRIPTION OF THE PREFERRED EMBODIMENTS

An embodiment of the present invention will be described in detail below with reference to the accompanying drawings.

A single-crystal substrate used in the embodiment of the present invention, that is, an R-cut substrate obtained by cutting an R-cut surface parallel to the R-face of synthetic quartz crystal will be described first.

Lumbered synthetic quartz crystal (SiO₂) is prepared first.

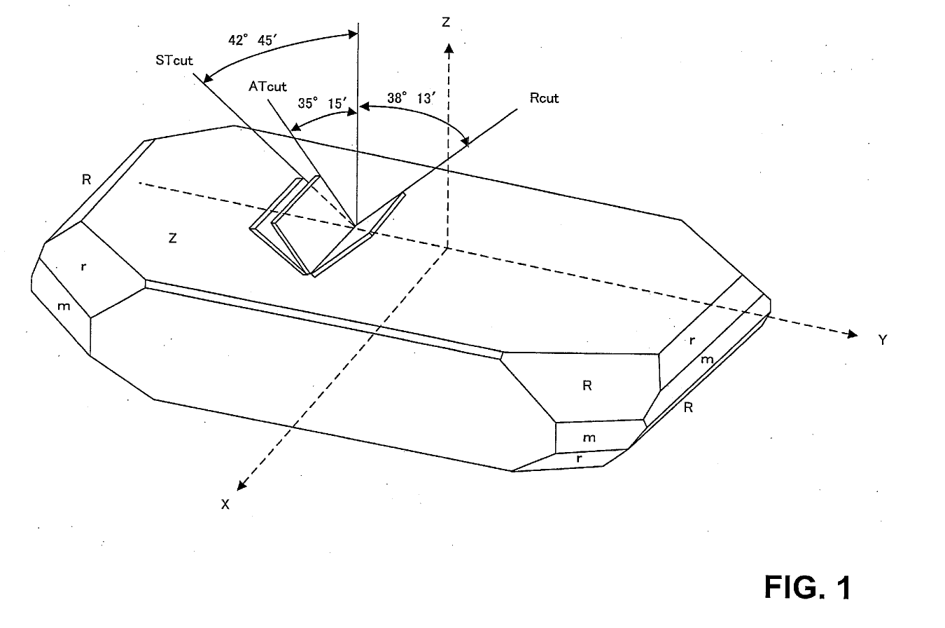

FIG. 1 is a perspective view of lumbered synthetic quartz crystal. The lumbered quartz crystal has a distinct prismatic face indicated by m, distinct pyramidal faces indicated by r and R, and three clear orthogonal crystallographic axes: the X-axis (electric axis), the Y-axis (machine axis), and the Z-axis (optic axis), as shown in FIG. 1. The r- and R-faces are known to be parallel to the X-axis and inclined by 38° 13′ with respect to the Y-axis. Of the pyramidal faces indicated by r and R, the pyramidal face with a larger area is defined as an R-face as the crystal grows more slowly on the R-face than on the r-face. Because the crystal of the quartz crystal grows more stably on the R-face than on the remaining faces, its crystal structure is smoother on the R-face than on the remaining faces.

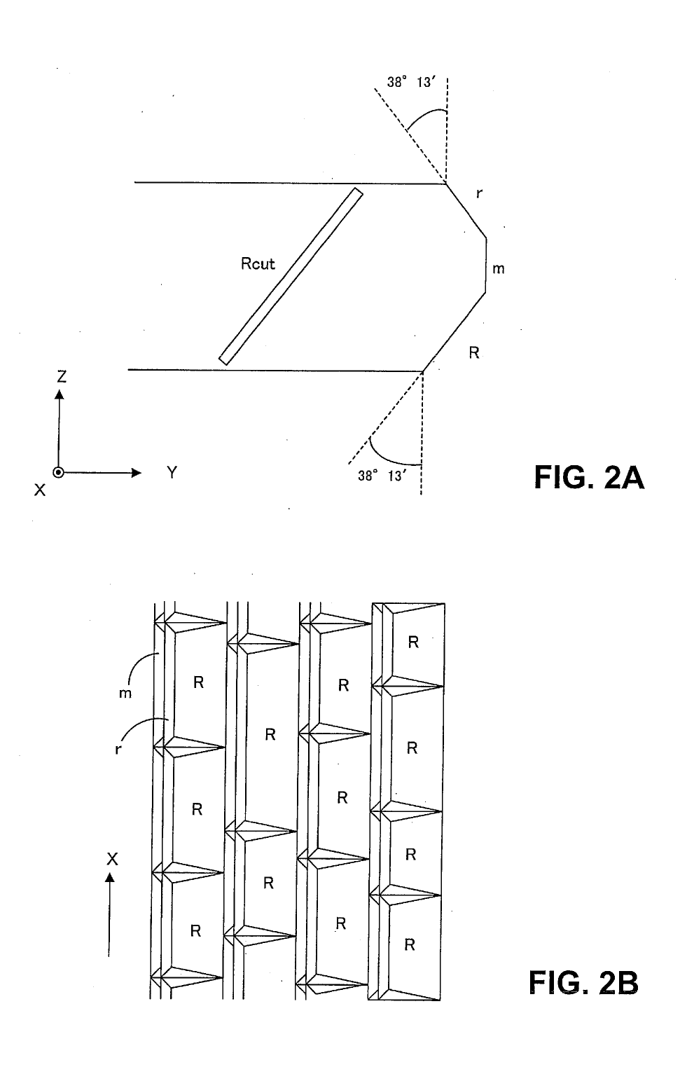

FIGS. 2A and 2B are views for explaining the crystal structure of an R-cut substrate according to the embodiment. More specifically, FIG. 2A is a sectional view of the synthetic quartz crystal when viewed from the X-direction, and FIG. 2B is a plan view of the R-cut substrate.

An R-cut substrate is prepared by cutting lumbered synthetic quartz crystal along a surface parallel to the R-face, as shown in FIG. 2A. The surface of the thus obtained R-cut substrate has a structure in which the R-face smoothest in terms of the crystal structure accounts for the most part of the surface, and the m- and r-faces are exposed on this surface to extend in a direction parallel to the X-axis albeit only slightly upon processing, as shown in FIG. 2B.

The R-cut surface of the thus obtained R-cut substrate is processed by mechanical mirror finishing to make it smoother.

The R-cut substrate having undergone the mirror finishing process is then annealed.

Upon the above-mentioned series of processes, a single-crystal substrate used in a method of manufacturing a carbon nanotube according to the embodiment of the present invention was obtained.

The surface of the thus obtained R-cut substrate was observed through an AFM (Atomic Force Microscope).

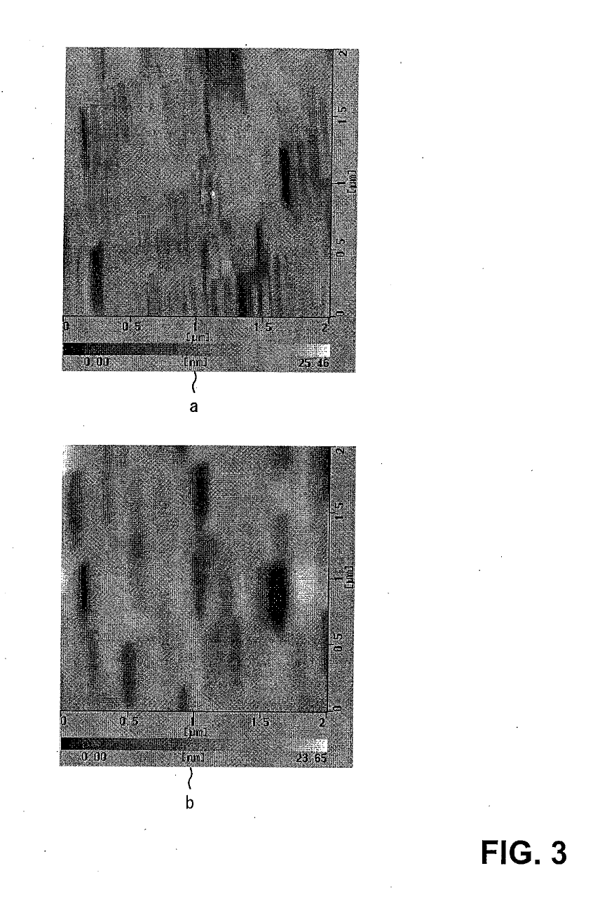

FIG. 3 shows AFM photographs of R-cut substrates according to the embodiment, in which a in FIG. 3 shows an AFM photograph of an unannealed R-cut substrate; and b in FIG. 3 shows an AFM photograph of an R-cut substrate annealed in the air at 900° C. for 13 hrs.

As can be seen from FIG. 3, upon the annealing of the R-cut substrate, the steps became sparser, so the surface of the R-cut substrate became smoother. This effect is considered to be produced because upon the annealing of the R-cut substrate, crystal clusters were violently agitated at high temperatures, thereby smoothing out a minute three-dimensional structure in a processing layer formed by mechanical processing.

Note that for the sake of reference, not only an R-cut substrate but also five types of cut substrates having cut surfaces different from the R-cut surface were prepared and their surfaces were observed through an AFM. More specifically, five types of substrates: an X-cut substrate having a normal parallel to the X-direction, a Y-cut substrate having a normal parallel to the Y-direction, a Z-cut substrate having a normal parallel to the Z-direction, an AT-cut substrate having a normal which is perpendicular to the X-axis and inclined by 35° 25′ with respect to the Y-axis, and an ST-cut substrate having a normal which is perpendicular to the X-axis and inclined by 42° 45′ with respect to the Y-axis were prepared and their surfaces were observed.

These five substrates were also processed by mechanical mirror finishing and then annealed in the air at 900° C. for 13 hrs to make their surfaces smoother.

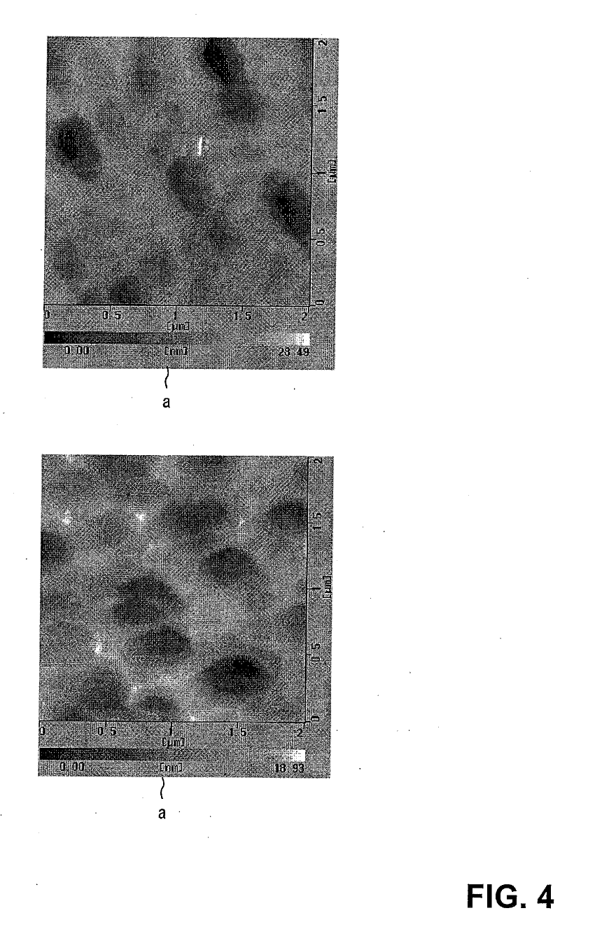

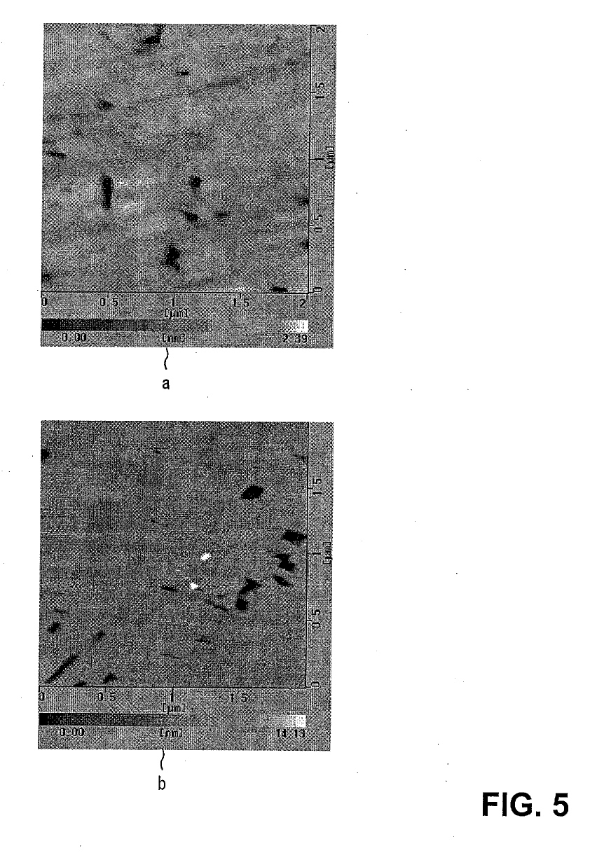

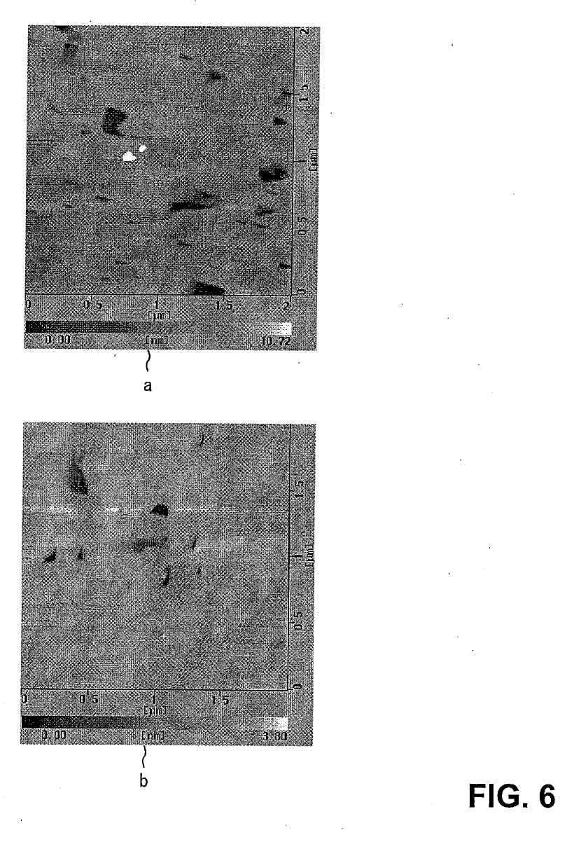

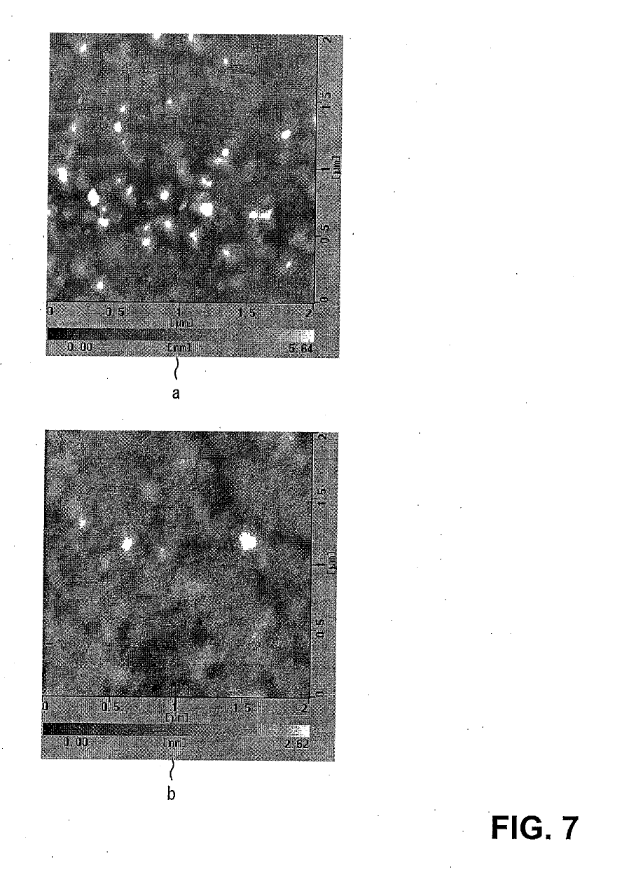

FIGS. 4 to 7 show AFM photographs of the ST-cut substrates, X-cut substrates, Y-cut substrates, and Z-cut substrates, respectively, before and after annealing.

As can be seen from comparisons among these AFM photographs, the surface of the R-cut substrate is smoother than the surfaces of the remaining substrates.

A method of manufacturing a carbon nanotube using the thus manufactured R-cut substrate will be described in detail next with reference to the accompanying drawings.

The arrangement of an experimental apparatus used in a method of manufacturing a carbon nanotube according to the embodiment will be described first.

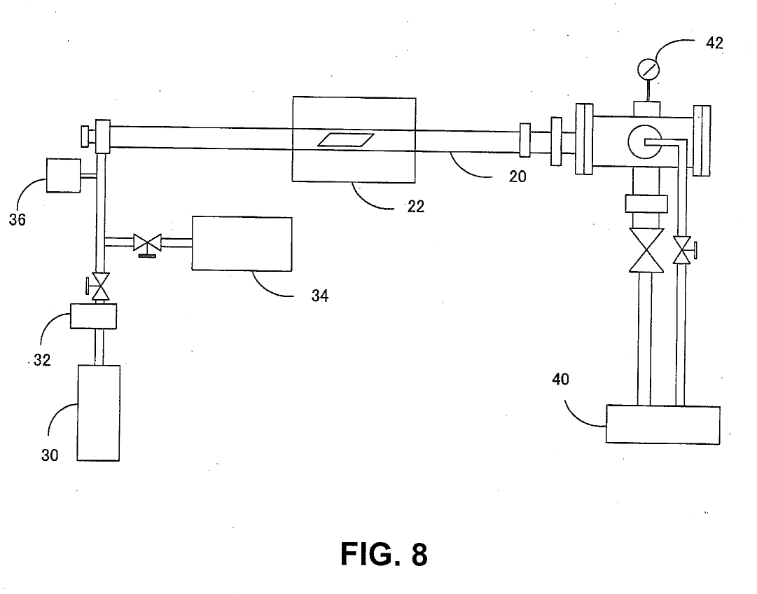

FIG. 8 is a view illustrating an example of the arrangement of an experimental apparatus used in a method of manufacturing a carbon nanotube according to the embodiment. This apparatus includes a quartz tube 20, electric furnace 22, gas mixture supply unit 30, gas flow control valve 32, alcohol supply unit 34, gas flow controller 36, rotary vacuum pump 40, and Pirani gauge 42, as shown in FIG. 8. The electric furnace 22 is positioned at the central portion of the quartz tube 20 and can heat a sample charged inside. The gas mixture supply unit 30 supplies a gas mixture of argon and hydrogen (3%) into the quartz tube 20. The gas flow control valve 32 controls the flow rate of the gas mixture of argon and hydrogen (3%) supplied from the gas mixture supply unit 30. The alcohol supply unit 34 can supply the vapor of an alcohol stored inside such as ethanol into the quartz tube 20 by heating the alcohol. The gas flow controller 36 controls the flow rates of the gas mixture of argon and hydrogen (3%) and the vapor of the alcohol. The vacuum pump 40 draws the gas in the quartz tube 20 by suction. The Pirani gauge 42 detects the degree of vacuum in the quartz tube 20.

Catalytic metals are arranged on an R-cut substrate first.

As a practical means for implementing this operation, a method of adhering iron and cobalt serving as catalytic metals to fine particles of USY zeolite, and spraying these fine particles of the USY zeolite onto the R-cut substrate is available. Note that USY zeolite having iron and cobalt adhered to it can be obtained by applying and spraying a slurry containing ferrous acetate (CH₃Coo)₂Fe, cobalt acetate tetrahydrate (CH₃COO)₂Co·4H₂O, USY zeolite, and ethanol (for example, at a ratio of 40 ml per gram of zeolite) onto an R-cut substrate, and drying the R-cut substrate using a dryer. In this manner, catalytic metals are sparsely supplied on an R-cut substrate because when catalytic metals are too dense on an R-cut substrate, carbon nanotubes grown using the catalytic metals as nuclei by processes (to be described later) may form bundles, or carbon nanotubes grown using fine particles of a certain catalytic metal as a nucleus may bend upon interactions with fine particles of other catalytic metals, thus degrading the orientation and linearity of the carbon nanotubes.

A procedure of manufacturing a carbon nanotube on an R-cut substrate, on which catalytic metals are arranged, using the above-mentioned experimental apparatus will be described next.

First, a substrate on which catalytic metals are arranged is charged into the quartz tube 20 up to the central portion of the electric furnace 22.

Then, the gas flow control valve 32 is opened to activate the vacuum pump 40 so that a gas mixture of argon and hydrogen (3%) in the gas mixture supply unit 30 is supplied to the electric furnace 22 while its flow rate is kept higher than a predetermined flow rate, thereby raising the temperature in the electric furnace 22 to a set temperature.

After the temperature in the electric furnace 22 has reliably risen to the set temperature, the gas flow control valve 32 is closed to stop the supply of the gas mixture of argon and hydrogen (3%) into the electric furnace 22.

An alcohol in the alcohol supply unit 34 is heated while the interior of the electric furnace 22 is maintained in a vacuum by the vacuum pump 40 to continuously supply the vapor of the alcohol into the electric furnace 22 for a predetermined period of time, thereby growing single-wall carbon nanotubes on the R-cut substrate in the electric furnace 22. Note that the flow rate of the alcohol is kept almost constant by changing the vapor pressure of the alcohol.

The inventors of the present invention report the result of observing through an SEM (Scanning Electron Microscope) carbon nanotubes formed on R-cut substrates as follows.

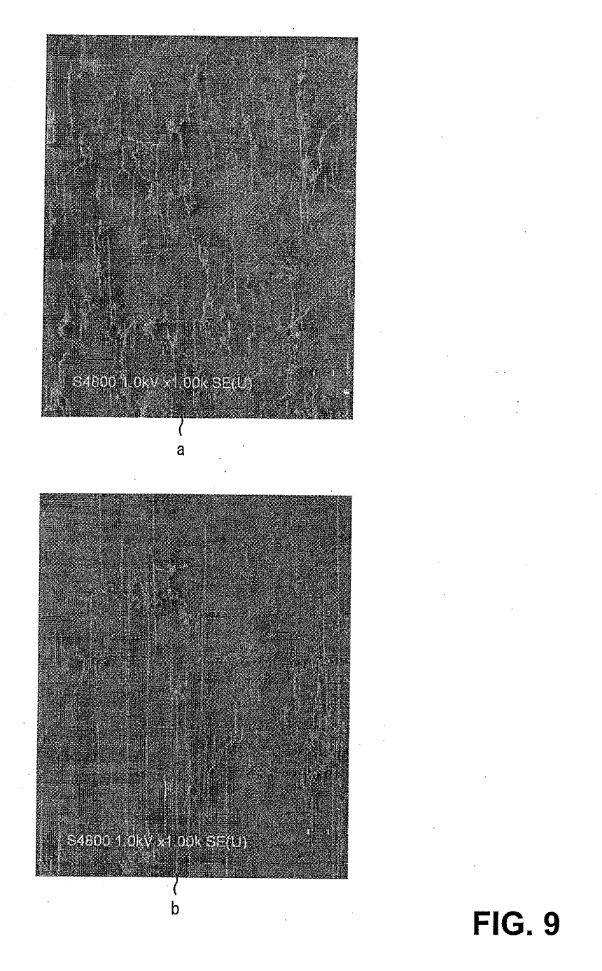

FIG. 9 shows SEM photographs of the surfaces of R-cut substrates, in which a in FIG. 9 shows an SEM photograph of an unannealed R-cut substrate; and b in FIG. 9 shows an SEM photograph of an annealed R-cut substrate. Carbon nanotubes were formed even on the unannealed R-cut substrate with an orientation in the X-direction, as shown in a of FIG. 9. However, carbon nanotubes were formed on the annealed R-cut substrate with a better orientation in the X-direction, as shown in b of FIG. 9.

Note that these SEM photographs were obtained by observing carbon nanotubes manufactured under the following conditions. First, an R-cut substrate on which iron and cobalt were arranged was charged into the electric furnace 22, and supplied with a gas mixture of argon and hydrogen (3%) at a flow rate of 200 sccm or more to raise the temperature in the electric furnace 22 to 800° C. The supply of the gas mixture of argon and hydrogen (3%) was then stopped, and ethanol in the alcohol supply unit 34 was heated while the interior of the electric furnace 22 was maintained in a vacuum to continuously supply the vapor of the ethanol into the electric furnace 22 at a flow rate of about 300 sccm for about 10 min, thereby growing carbon nanotubes on the R-cut substrate. These carbon nanotubes were examined by resonant Raman spectroscopy, and confirmed as single-wall carbon nanotubes with high quality.

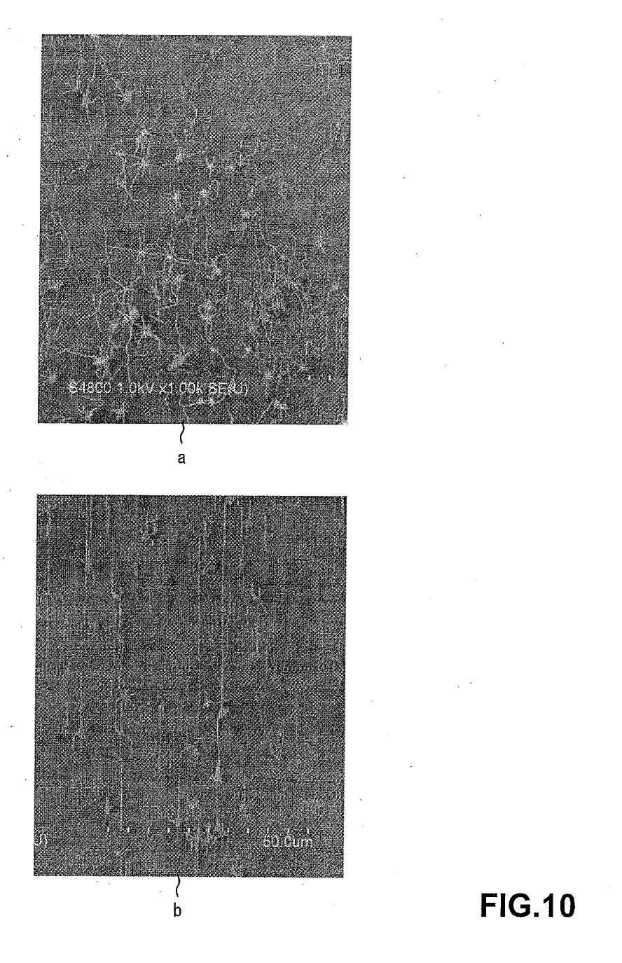

FIGS. 10 to 14 are SEM photographs of AT-cut substrates, ST-cut substrates, X-cut substrates, Y-cut substrates, and Z-cut substrates, respectively. SEM photographs of both unannealed and annealed cut substrates are presented in each of FIGS. 10 to 14.

Carbon nanotubes formed on the unannealed AT-cut substrate had no significant orientation, as shown in a of FIG. 10. However, as can be seen from b of FIG. 10, carbon nanotubes were formed on the annealed AT-cut substrate with a good orientation and linearity in the X-direction, although not as good as those of the carbon nanotubes formed on the annealed R-cut substrate.

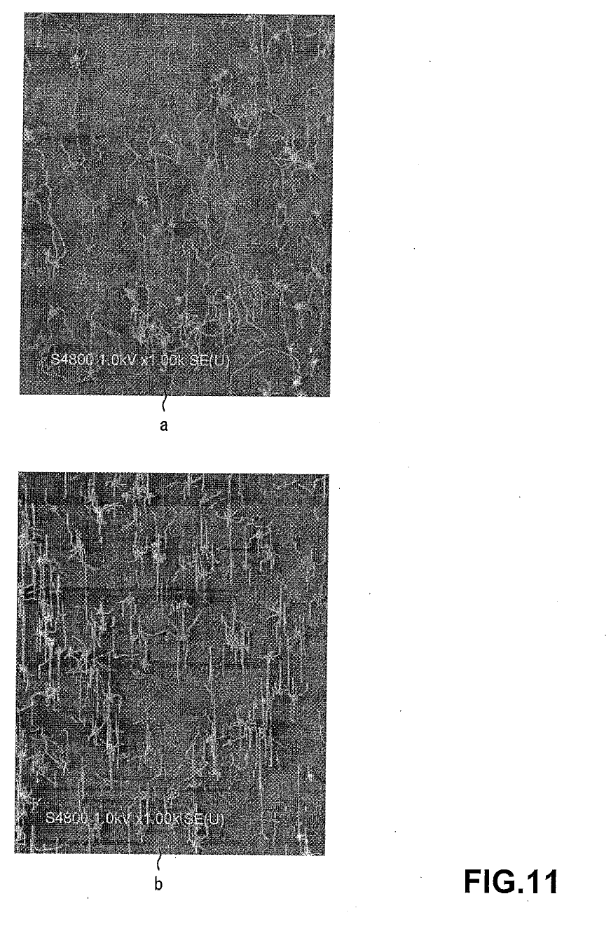

Carbon nanotubes formed on the unannealed ST-cut substrate were observed to be slightly oriented in the X-direction, as shown in a of FIG. 11. However, as can be seen from b of FIG. 11, carbon nanotubes were formed on the annealed ST-cut substrate with a good orientation and linearity in the X-direction, although not as good as those of the carbon nanotubes formed on the annealed R-cut substrate.

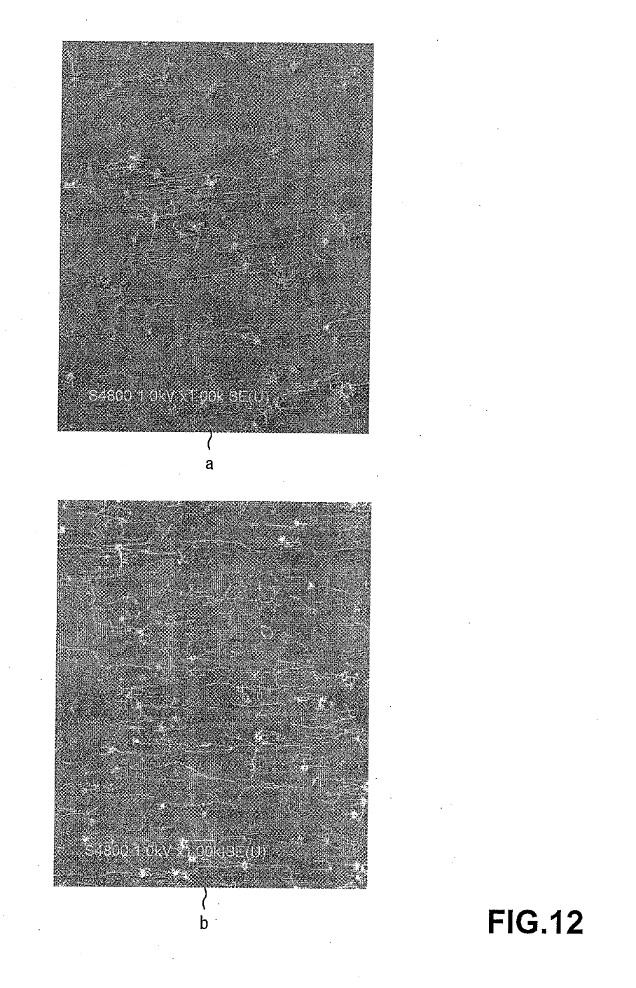

Carbon nanotubes formed on the X-cut substrate were observed to be slightly oriented in the Z-direction, regardless of whether this substrate is annealed or unannealed, as shown in a and b of FIG. 12. However, as can be seen from a and b of FIG. 12, the carbon nanotubes formed on the X-cut substrate have an orientation and linearity poorer than those of the carbon nanotubes formed on the R-cut substrate and ST-cut substrate.

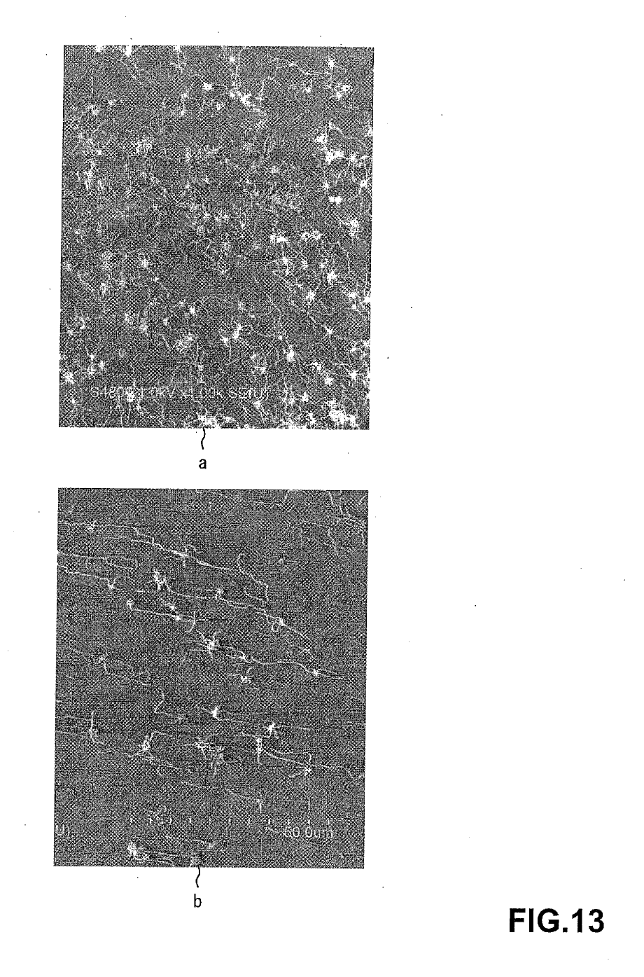

Carbon nanotubes formed on the unannealed Y-cut substrate had neither a significant orientation nor linearity, as shown in a of FIG. 13. However, as can be seen from b of FIG. 13, carbon nanotubes were formed on the annealed Y-cut substrate with a good orientation and linearity in the X-direction, although not as good as those of the carbon nanotubes formed on the R-cut substrate, ST-cut substrate, and AT-cut substrate.

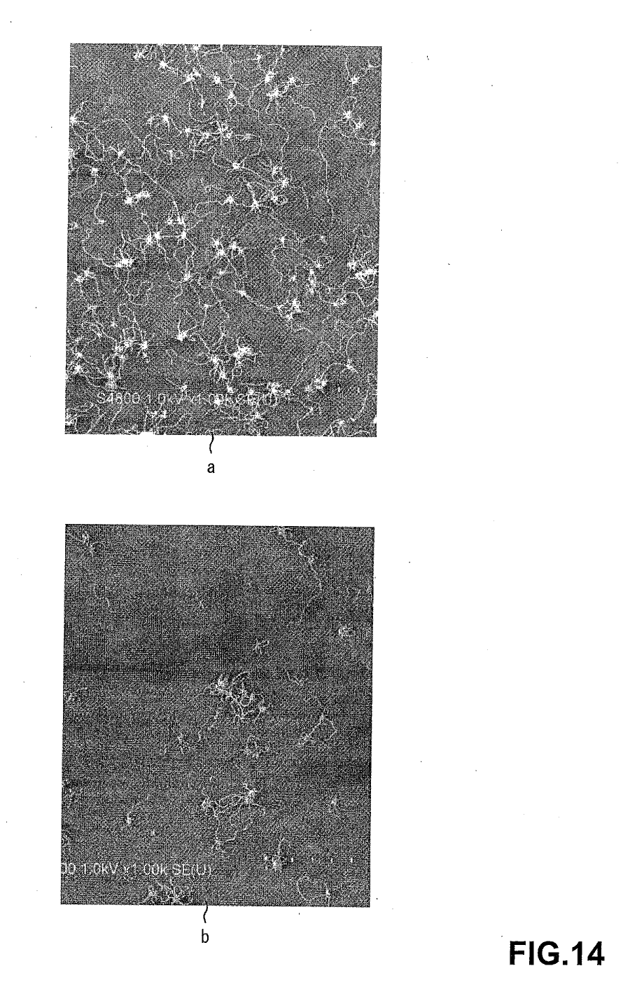

As can be seen from a and b of FIG. 14, carbon nanotubes formed on the Z-cut substrate had neither an orientation nor linearity, regardless of whether this substrate is annealed or unannealed.

These results reveal that carbon nanotubes can be formed with a better orientation and linearity on an R-cut substrate, especially, on an annealed R-cut substrate, than on an AT-cut substrate, an ST-cut substrate, an X-cut substrate, a Y-cut substrate, and a Z-cut substrate.

As described above, according to this embodiment, an R-cut substrate having a surface cut parallel to an R-face smoothest in terms of the crystal structure is used, so the R-face smoothest in terms of the crystal structure accounts for the most part of the surface of the R-cut substrate even after processing. Hence, the use of a single-crystal substrate for manufacturing a carbon nanotube as mentioned above allows the carbon nanotube to grow on the smoothest R-face, thereby manufacturing a carbon nanotube with a good orientation and linearity in accordance with the crystal lattice arrangement.

Although a carbon nanotube is manufactured using R-cut synthetic quartz crystal as a single-crystal substrate in this embodiment, R-cut sapphire may be used as a single-crystal substrate.

Also, although a carbon nanotube is manufactured using the CVD method by supplying an alcohol onto an R-cut substrate having fine particles of catalytic metals arranged on its surface in this embodiment, it may be manufactured using the CVD method by supplying another carbon source gas such as carbon monoxide or methane.

Moreover, although catalytic metals are adhered to fine particles of USY zeolite and those particles are sprayed on an R-cut substrate in this embodiment, they may be arranged on an R-cut substrate by, for example, the vacuum deposition or sputtering method. In this case, the surface of the R-cut substrate may be divided into a portion in which the catalytic metals are arranged and a portion in which they are not arranged, using liftoff of the photolithography method.

In addition to the above-mentioned methods, a method of directly arranging metal catalysts on an R-cut substrate can also be adopted. More specifically, an R-cut substrate is immersed in a solution obtained by dissolving cobalt acetate (or a mixture of cobalt acetate and molybdenum acetate) in ethanol. After a while, the R-cut substrate is slowly pulled out of the solution, and heated to a temperature of about 400° C. in the atmosphere to oxidize the solution adhered to the surface of the R-cut substrate. Upon such a process, cobalt fine particles (or fine particles of cobalt and molybdenum) can be uniformly formed on the surface of the R-cut substrate.

Again, although iron (Fe) and cobalt (Co) are used as catalytic metals, ruthenium (Ru) or osmium (Os) in group VIII, rhodium (Rh) or iridium (Ir) in group IX, and nickel (Ni), lead (Pb), or platinum (Pt) in group X, for example, can be used. Further, molybdenum (Mo) or rhodium (Rh) may be added as an auxiliary catalytic metal.

### EXAMPLE

An Example of the present invention will be described in detail next with reference to the accompanying drawings.

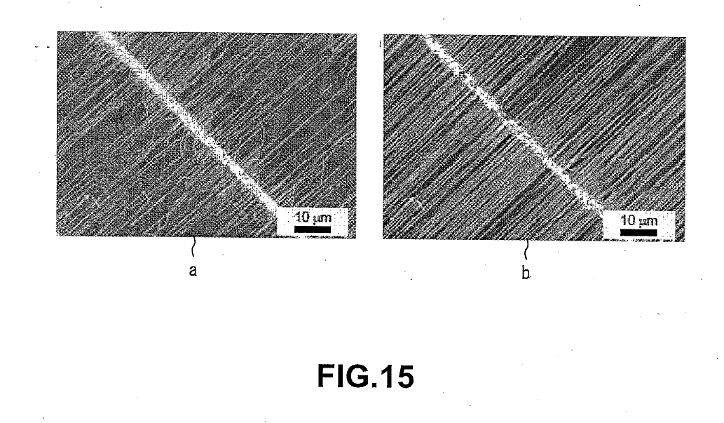

First, the influence that an etching process on an R-cut substrate has on single-wall carbon nanotubes was examined. FIG. 15 shows SEM photographs for explaining the influence that an etching process on an R-cut substrate has on single-wall carbon nanotubes, in which a in FIG. 15 shows an SEM photograph of an unetched R-cut substrate; and b in FIG. 15 shows an SEM photograph of an etched R-cut substrate.

As can be seen from a and b of FIG. 15, the orientation of single-wall carbon nanotubes improves upon an etching process. It has already been confirmed based on comparisons with SEM photographs (not shown) that a relatively large number of polishing traces are formed in an unetched R-cut substrate, while a relatively small number of polishing traces are formed in an etched R-cut substrate. Accordingly, the orientation of single-wall carbon nanotubes is expected to improve as the number of polishing traces reduces. In other words, the orientation of single-wall carbon nanotubes is poor in the vicinities of polishing traces due to deterioration in R-face structure, but an etching process reduces these polishing traces and therefore can suppress degradation in orientation due to factors associated with the polishing traces.

As can be seen from a and b of FIG. 15 as well, the density of single-wall carbon nanotubes increases upon an etching process. When single-wall carbon nanotubes come into contact with each other, they mutually hinder their growth, as observed in a of FIG. 15. However, an etching process can improve the orientation of single-wall carbon nanotubes, and is therefore considered to have made it possible to suppress the adverse effect produced as the single-wall carbon nanotubes come into contact with each other.

Next, the influence that the partial pressure of ethanol at the time of CVD has on single-wall carbon nanotubes formed on an R-cut substrate was examined.

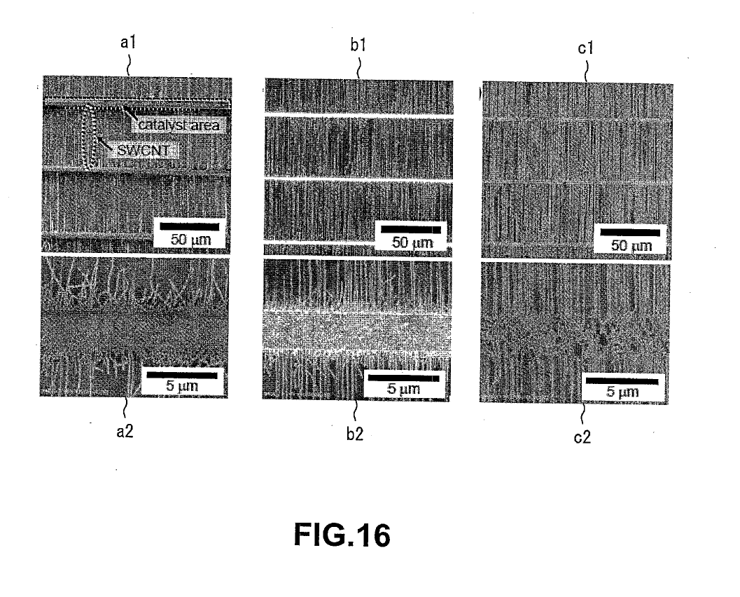

FIG. 16 shows SEM photographs for explaining the influence that the partial pressure of ethanol at the time of CVD has on single-wall carbon nanotubes. The partial pressure of ethanol at the time of CVD is 1,300 Pa in a1 and a2 of FIG. 16, 300 Pa in b1 and b2 of FIGS. 16, and 60 Pa in c1 and c2 of FIG. 16. a1, b1, and c1 in FIG. 16 are SEM photographs of horizontally oriented single-wall carbon nanotubes, and a2, b2, and c2 in FIG. 16 are enlarged SEM photographs of the vicinities of catalyst areas. Note that a gas containing argon and hydrogen was used as a carrier gas in c1 and c2 in FIG. 16. The density of synthetic horizontally oriented single-wall carbon nanotubes was 0.9/μm in a1 of FIG. 16, 3.3/μm in b1 of FIGS. 16, and 4.9/μm in c1 of FIG. 16. As the partial pressure of ethanol lowers, the density of horizontally oriented single-wall carbon nanotubes increases.

On the other hand, as can be seen from enlarged SEM photographs of the vicinities of a catalyst area, shown in a2, b2, and c2 of FIG. 16, a minimum amount of single-wall carbon nanotubes was formed in the catalyst portion at a minimum partial pressure of ethanol in the case of c2 in FIG. 16. This fact coincides with the conventional experimental results, so the total amount of synthesis of single-wall carbon nanotubes was confirmed to reduce upon a decrease in partial pressure of ethanol.

These results reveal that upon a decrease in partial pressure of ethanol, the total amount of synthesis of single-wall carbon nanotubes reduced, but the amount and density of horizontally oriented single-wall carbon nanotubes increased. The inventors of the present invention examined the cause of this phenomenon, and concluded that when the partial pressure of ethanol is relatively high, interactions such as banding among single-wall carbon nanotubes in the catalyst area stop the growth of horizontally oriented single-wall carbon nanotubes, thus hampering an increase in density of horizontally oriented single-wall carbon nanotubes. More specifically, when the partial pressure of ethanol is high, a large number of single-wall carbon nanotubes simultaneously start their growth and form bundles, and this increases the probability that single-wall carbon nanotubes will grow in a direction away from the substrate without coming into contact with the substrate, as seen in vertically oriented single-wall carbon nanotubes, thus reducing the density of horizontally oriented single-wall carbon nanotubes. In contrast to this, when the partial pressure of ethanol is low, the total amount of synthesis of single-wall carbon nanotubes reduces and the frequency of the start of growth of single-wall carbon nanotubes lowers at the same time, thus reducing interactions among the single-wall carbon nanotubes. This means that as the partial pressure of ethanol lowers, the probability that single-wall carbon nanotubes will grow with a good orientation upon coming into contact with the substrate without bundling increases, thus increasing the density of horizontally oriented single-wall carbon nanotubes.

A Raman scattering experiment was conducted while changing the position at which synthetic horizontally oriented single-wall carbon nanotubes are irradiated with a laser.

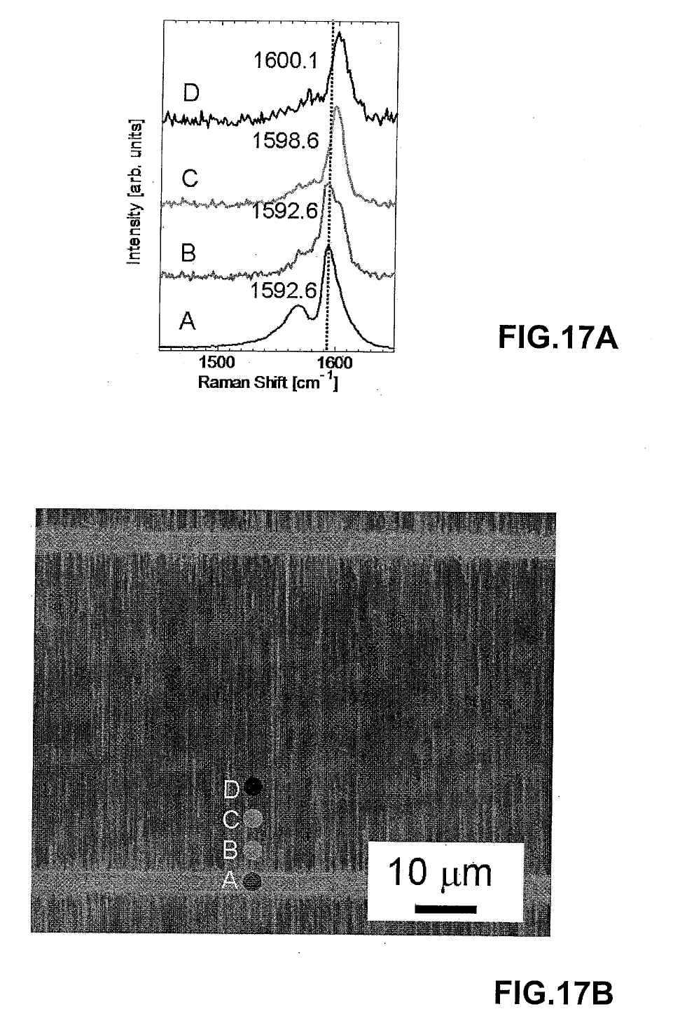

FIGS. 17A and 17B are views for explaining the result of a Raman scattering experiment for horizontally oriented single-wall carbon nanotubes. More specifically, FIG. 17A shows the Raman spectra of horizontally oriented single-wall carbon nanotubes, which were measured at positions 0 μm, 5 μm, 10 μm, and 15 μm from a catalyst area, and FIG. 17B shows a CCD photograph of a sample surface captured by an optical microscope which forms a Raman spectroscopic device. A portion indicated by an arrow in FIG. 17B is a catalyst area, and the Raman spectra were measured at positions 0 μm, 5 μm, 10 μm, and 15 μm from the catalyst area, as indicted by four dots. Because the Raman spectrum on the catalyst area exhibits a G-band as a feature of single-wall carbon nanotubes, single-wall carbon nanotubes were confirmed to be synthesized, as shown in FIG. 17A. As indicated by a dotted line in FIG. 17A, the peak position of the G-band was confirmed to have a typical value of 1,592 cm⁻¹. While the peak position remains the same in the Raman spectrum at the position 5 μm from the catalyst area, it changes to 1,598 cm⁻¹ in the Raman spectrum at the position 10 μm from the catalyst area, and to 1,600 cm⁻¹ in the Raman spectrum at the position 15 μm from the catalyst area, so the peak position of the G-band shifts to the high frequency side in a direction away from the catalyst area.

Note that the phenomenon that the G-band shifts to the high frequency side has been reported to be caused by the interaction between the single-wall carbon nanotubes and the quartz crystal substrate. Hence, it is surmised that the G-band obtained from horizontally oriented single-wall carbon nanotubes which are in contact with the substrate shifts to the high frequency side, while the G-band obtained from random single-wall carbon nanotubes which are not in contact with the substrate does not shift to the high frequency side.

Therefore, it is considered that while a large number of random single-wall carbon nanotubes are present in the catalyst area, the ratio of oriented single-wall carbon nanotubes to random single-wall carbon nanotubes increases in a direction away from the catalyst area.

Note that the position of the RBM, that is, the peak correlated with vibration of single-wall carbon nanotubes in the diameter direction overlaps that of the peak resulting from factors associated with the quartz crystal, and therefore could hardly be observed. This made it impossible to analyze the diameter distribution of horizontally oriented single-wall carbon nanotubes from the Raman spectrum. This is presumably because the amount of synthesis of single-wall carbon nanotubes is small (the density of single-wall carbon nanotubes is low), and the single-wall carbon nanotubes are in contact with the substrate so the peak is weak.

The height of a catalyst on the surface of a sample was measured through an AFM next.

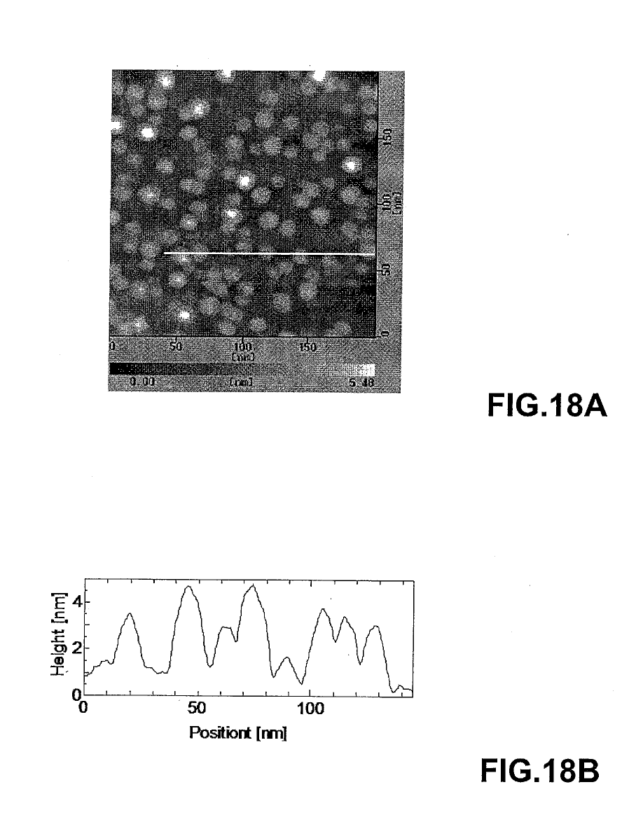

Upon preparation of an unetched R-cut substrate, iron was deposited on the entire surface of the R-cut substrate at a thickness of 0.2 nm without photolithography, the R-cut substrate was heated in the air at 550° C. for 10 min, and the R-cut substrate was further heated in a gas containing argon and hydrogen to a temperature of 800° C. to chemically reduce it, thereby using a substrate completed without introducing ethanol as a sample. FIGS. 18A and 18B are views showing the measurement results obtained by an AFM. More specifically, FIG. 18A is an AFM photograph of the surface of this sample, and FIG. 18B is a graph showing the height profile of a portion indicated by a solid line in FIG. 18A. As can be seen from FIGS. 18A and 18B, the reduced catalyst fine particles have a diameter of about 1 to 4 nm and a density of about 3.0×10³/μm².

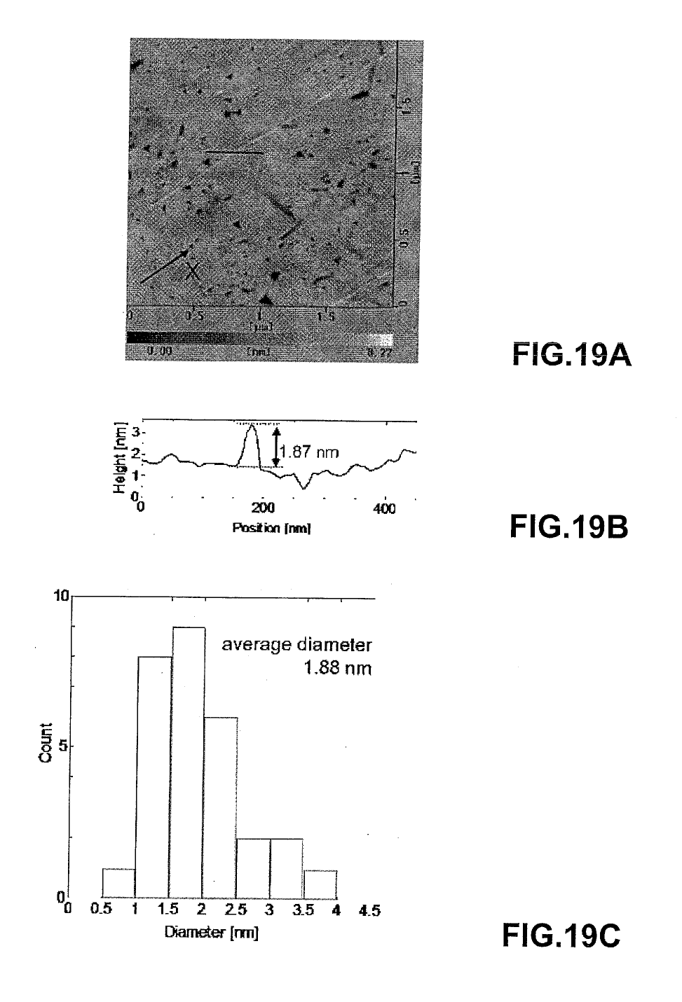

Also, horizontally oriented single-wall carbon nanotubes were observed through an AFM. FIGS. 19A, 19B, and 19C are views showing the observation results of unetched R-cut substrates obtained by an AFM. More specifically, FIG. 19A is an AFM photograph of horizontally oriented single-wall carbon nanotubes synthesized using an unetched R-cut substrate, FIG. 19B is a graph showing the height profile of a portion indicated by a solid line in FIG. 19A, and FIG. 19C is a distribution map of the diameters of 29 horizontally oriented single-wall carbon nanotubes, which are derived from the height profiles of the horizontally oriented single-wall carbon nanotubes. Single-wall carbon nanotubes were observed to be horizontally oriented in the X-direction of the quartz crystal in the AFM photograph shown in FIG. 19A. Also, the diameter of the single-wall carbon nanotubes was estimated to be 1.87 nm from the height profile shown in FIG. 19B. Similarly, when the height profile of the 29 single-wall carbon nanotubes was measured to derive their diameter distribution, an average diameter of 1.88 nm was obtained, as shown in FIG. 19C.

However, because it cannot be determined based on the AFM photograph whether the measured single-wall carbon nanotubes are independent single-wall carbon nanotubes, these single-wall carbon nanotubes may include bundles of single-wall carbon nanotubes. Also, the difference between the interaction between the AFM probe and the substrate and the interaction between the probe and the single-wall carbon nanotubes, if any, may influence the height profile.

### INDUSTRIAL APPLICABILITY

The present invention is applicable to, for example, the manufacturing industry of carbon nanotubes.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A method of manufacturing a carbon nanotube comprising:
arranging a catalytic metal on an R-cut surface of a single-crystal substrate, which is cut parallel to an R-face of a single crystal; and
heating the single-crystal substrate to a predetermined temperature and then supplying a carbon source gas to form a carbon nanotube on the R-cut surface using the catalytic metal as a nucleus.

2. A method of manufacturing a carbon nanotube according to claim 1, wherein the single-crystal substrate is annealed.

3. A method of manufacturing a carbon nanotube according to claim 1, wherein the single-crystal substrate has the R-cut surface processed by minor finishing.

4. A method of manufacturing a carbon nanotube according to claim 1, wherein the single-crystal substrate is one of a single-crystal sapphire substrate and a single-crystal quartz substrate.

5. A method of manufacturing a carbon nanotube according to claim 1, wherein the carbon nanotube includes a single-wall carbon nanotube.

6. A single-crystal substrate for manufacturing a carbon nanotube used in a method of manufacturing a carbon nanotube, the method comprising:
arranging a catalytic metal on a surface of a single-crystal substrate; and
heating the single-crystal substrate to a predetermined temperature and then supplying a carbon source gas to form a carbon nanotube on the surface using the catalytic metal as a nucleus,
the substrate comprising an R-cut surface cut parallel to an R-face of a single crystal.

7. A carbon nanotube formed on a single-crystal substrate, wherein
the single-crystal substrate comprises an R-cut surface cut parallel to an R-face of a single crystal, and
the carbon nanotube is formed on the R-cut surface.
